(19) United States
(12) Patent Application Publication
(10) Pub. No.: US 2026/0228379 A1
(43) Pub. Date: Aug. 6, 2026

(54) MONITORING PATH DESIGN APPARATUS, MONITORING PATH DESIGN METHOD AND PROGRAM

(71) Applicant: NIPPON TELEGRAPH AND TELEPHONE CORPORATION, Tokyo (JP)

(72) Inventor: Hiroki IKEUCHI, Tokyo (JP)

(21) Appl. No.: 18/868,997

(22) PCT Filed: Jun. 20, 2022
(86) PCT No.: PCT/JP2022/024610

§ 371 Date: Nov. 25, 2024

(51) Int. Cl. G06F 30/18

(52) U.S. Cl. CPC G06F 30/18

(57) ABSTRACT

According to an aspect of the present disclosure, a monitoring path design device designs a monitoring path for estimating a state of a target network. The monitoring path design device includes an objective function generation unit configured to generate an objective function representing effectiveness of the monitoring path in a form that is calculable by an Ising machine using an undirected graph representing a topology of the target network.

### TECHNICAL FIELD

The present disclosure relates to a monitoring path design device, a monitoring path design method, and a program.

### BACKGROUND ART

To stably operate a network system, it is important to estimate various states (for example, a delay, a fault, or the like) of a target network. Therefore, in recent years, active monitoring has often been performed in addition to passive monitoring for collecting logs, metrics, and the like from an NW device. The active monitoring is a monitoring scheme in which end-to-end measurement for a target network is performed using ping or the like, and a state is estimated from measurement values such as communicability and a round-trip time (RTT). A technique for estimating a state of a target network by such end-to-end measurement is also called network tomography or the like and has been actively studied.

In network tomography, not only a network state estimation method (Non Patent Literature 1) but also how to design a highly effective monitoring path in the network state estimation is crucial. In fact, a scheme of defining an objective function representing effectiveness of a monitoring path and then searching for a path design for maximizing the objective function has been proposed (Non Patent Literature 2).

The problem of designing monitoring paths that are highly effective in estimating binary states representing normal or abnormal nodes and links on a network n the network tomography will be considered. In the network tomography, end-to-end measurement is performed between a plurality of distant nodes. A path along which a test packet is routed at this time is referred to as a monitoring path. It is desirable to design the monitoring path in advance from the viewpoint of cost, operability, and the like. Since there are various network states (variations of fault points), the monitoring path in which various states can be separate is considered excellent. However, when a network scale is large, it is mathematically difficult to design an optimum monitoring path. In Non Patent Literature 2, the effectiveness of the monitoring path is defined by a function called distinguishability, and maximization is attempted by an algorithm based on a greedy method. However, only an approximate optimum solution can be obtained by this method.

On the other hand, in recent years, a computer called an Ising machine has become known (Non Patent Literatures 3 and 4). Many calculation examples showing higher performance than classical computers have been reported. In the Ising machine, a combinatorial optimization problem expressed in a format of higher order binary optimization (HOBO) or higher order binary optimization (QUBO) can be solved. A general methodology for lowering the degree of HOBO to QUBO is also known (Non Patent Literature 5).

### CITATION LIST

### Non Patent Literature

Non Patent Literature 1: Duffield, Nick. “Simple network performance tomography.” Proceedings of the 3rd ACM SIGCOMM conference on Internet measurement. 2003.
Non Patent Literature 2: He, Ting, et al. “Service placement for detecting and localizing failures using end-to-end observations.” 2016 IEEE 36th International Conference on Distributed Computing Systems (ICDCS). IEEE, 2016.
Non Patent Literature 3: Johnson, Mark W., et al. “Quantum annealing with manufactured spins.” Nature 473.7346 (2011): 194-198.
Non Patent Literature 4: Inagaki, Takahiro, et al. “A coherent Ising machine for 2000-node optimization problems.” Science 354.6312 (2016): 603-606.
Non Patent Literature 5: Dattani, Nike. “Quadratization in discrete optimization and quantum mechanics.” arXiv preprint arXiv: 1901.04405 (2019).

### SUMMARY OF INVENTION

### Technical Problem

If a problem that maximizes distinguishability indicating effectiveness of a monitoring path can be formulated in the form of HOBO or QUBO, it is considered that a more effective monitoring path can be obtained as an optimum solution by an Ising machine.

The present disclosure has been made in view of the foregoing viewpoints and provides a technique for designing a highly effective monitoring path.

### Solution to Problem

According to an aspect of the present disclosure, a monitoring path design device designs a monitoring path for estimating a state of a target network. The monitoring path design device includes an objective function generation unit configured to generate an objective function representing effectiveness of the monitoring path in a form that is calculable by an Ising machine using an undirected graph representing a topology of the target network.

### Advantageous Effects of Invention

A technique for designing a highly effective monitoring path is provided.

### BRIEF DESCRIPTION OF DRAWINGS

FIG. 1 is a diagram illustrating Formula (3).

FIG. 2 is a diagram illustrating Formula (4).

FIG. 3 is a diagram illustrating Formula (5).

FIG. 4 is a diagram illustrating an example of a hardware configuration of a monitoring path design device according to an embodiment.

FIG. 5 is a diagram illustrating an example of a functional configuration of a monitoring path design device according to the embodiment.

FIG. 6 is a flowchart illustrating an example of a monitoring path design process according to the embodiment.

### DESCRIPTION OF EMBODIMENTS

Hereinafter, an embodiment of the present invention will be described. In the following embodiment, a scheme of formulating a problem that maximizes distinguishability indicating effectiveness of a monitoring path into a form of HOBO or QUBO is proposed. A monitoring path design device 10 capable of designing a highly effective monitoring path using an Ising machine by a proposed technique will be described.

### <Proposed Scheme>

First, the proposed technique will be described.

<<Positioning of Ising Machine and Proposed Technique>>

The proposed scheme provides a formulation method for performing calculation on an Ising machine. Therefore, the Ising machine will first be described in brief, and positioning of the proposed technique will be revealed.

First, an Ising model that is a basis of the Ising machine will be described. The Ising model is a mathematical model originally proposed to describe thermal behavior of a magnetic body, and originates from statistical mechanics, A Hamiltonian function H (this function is also called an Ising Hamiltonian or simply a Hamiltonian) representing energy of a system is given by the following Formula (1).

$$\begin{matrix}[ Math . 1 ] & \\ ℋ ( {\{ {s}_{i} \}}_{i} ; {\{ {J}_{i j} \}}_{i , j} , {\{ {h}_{i} \}}_{i} ) = {\sum }_{i , j}^{N} {J}_{i j} {s}_{i} {s}_{j} + {{\sum }_{i}}^{N} {H}_{i} {s}_{i} & ( 1 )\end{matrix}$$

Here, sᵢ∈{±1} is a spin variable (where i=1, 2, . . . , N) representing magnitude of a spin i. Jᵢⱼ∈R (where R is the set of all real numbers) is a coefficient of interaction (i, j=1, 2, . . . , N) of spins i and j. Hᵢ∈R is a magnetic field coefficient (where i=1, 2, . . . , N) applied to the spin i. In text of the specification, H with no subscript represents a Hamiltonian function, and Hᵢ with a subscript represents a magnetic field coefficient.

In the case of a normal Ising model, it is often considered that the spins are aligned in any dimensional lattice, interaction occurs only between nearest neighbor spins, and a magnetic field is uniform (that is, a magnetic field coefficient Hᵢ does not depend on i) for all spins. However, here, the spins are arranged on a complete graph, the interaction coefficient Jᵢⱼ is assumed to occur between all the spins, and the magnetic field is also allowed to be nonuniform. Physically, a state {sᵢ}ᵢ where the Hamiltonian takes a small value is often implemented in a system at a low temperature, which means that the spins i and j are easily aligned (alternatively, it is difficult to align the spins) when Jᵢⱼ<0 (or Jᵢⱼ>0) and the spin variable sᵢ easily takes −1 (or +1) when Hᵢ>0 (or Hᵢ<0). It is not always easy to obtain lowest energy and a state of the lowest energy (ground state) depending on a graph shape of the spin arrangement and magnitude of various coefficients, and a combinatorial optimization problem having a large number of local optimum solutions is caused.

Examples of a computer using the Ising model include a quantum annealing machine (Non Patent Literature 3) and a coherent Ising machine (Non Patent Literature 4). Hereinafter, these are collectively referred to as an Ising machine. It is assumed that the Ising machine is a mechanism that gives a ground state of a system that can be expressed by the foregoing Hamiltonian and its energy, and any Ising machine can be used.

If the combinatorial optimization problem can be converted into a form of the foregoing Hamiltonian, lowest energy of the Hamiltonian and its ground state (that is, a minimum value and the optimum solution of the objective function) are obtained using the Ising machine. In general, as described in the following step 1 to step 4, a form of quadratic order unconstrained binary optimization (QUBO) is often used.
Step 1: Converting the combinatorial optimization problem into QUBO
Step 2: Converting QUBO into a form of an Ising Hamiltonian (that is, QUBO is converted into an Ising model)
Step 3: Converting the Ising Hamiltonian into a form that can be solved by an Ising machine (that is, embedded in a physical model)
Step 4: Performing optimization

The foregoing step 2 is performed through variable conversion, and the foregoing step 3 is performed according to a procedure specific to the Ising machine. However, a tool that can be automatically performed has been developed and can be implemented by a technique of the related art. However, there are cases in which an auxiliary bit is required in the embedding in the physical model in the foregoing step 3. It is necessary to pay attention to that point when the number of usable bits is limited.

Therefore, when it is desired to solve an original combinatorial optimization problem, it is sufficient to focus on the foregoing step 1.

QUBO is an optimization problem in which an objective function is expressed in a form represented by the following Formula (2).

$$\begin{matrix}[ Math . 2 ] & \\ E ( {\{ {x}_{i} \}}_{i} ; {\{ {a}_{i j} \}}_{i , j} , {\{ {b}_{i} \}}_{i} ) = {\sum }_{i , j}^{N} {a}_{ij} {x}_{i} {x}_{j} + {\sum }_{i}^{N} {b}_{i} {x}_{i} & ( 2 )\end{matrix}$$

Here, xᵢ∈{0, 1} (where i=1, 2, . . . , N) is a variable, and {aᵢⱼ}ᵢⱼ and {bᵢ}ᵢ are real-valued coefficients. An explicit constraint cannot be given to an executable area of the variable {xᵢ}ᵢ, but when it is desired to impose some equality constraints or inequality constraints, an optimum solution substantially satisfying the constraint can be obtained by incorporating the constraints in the form of a relaxation term in the objective function. There may be a case where the optimization problem is formulated into HOBO including higher-order terms of the third order or more depending on the combinatorial optimization problem. However, since there is also a general methodology of lowering HOBO to the degree of QUBO (Non Patent Literature 5), it can be said that a problem class to which a solution by the Ising machine can be applied is extremely wide. However, when HOBO is converted into QUBO, it is necessary to add an auxiliary bit, which is expected to make a functional type of the objective function complicated. Therefore, it is considered that a more optimum solution can be easily obtained by individually designing QUBO having a simple form by well ascertaining a property of a problem desired to be solved rather than performing a process of representing the problem desired to be solved by HOBO and then converting the problem into QUBO according to general methodology.

Hereinafter, a scheme for converting a monitoring path design problem in network tomography into HOBO or QUBO (that is, a scheme of a portion corresponding to the foregoing step 1) will be proposed. This proposed technique is commonly applicable to any Ising machine. The subsequent steps 2 and 3 can be implemented by the technique of the related art such as an automatic execution tool as described above.

### <<Problem Setting>>

First, mathematical terms and concepts are prepared.

### Graph Representing Target Network

A target network is represented by a simple (that is, there are no multiple sides or loops.) connected undirected graph G=(V, E). A node v∈V represents, for example, a network device such as a router. A link e∈E represents, for example, a link between network devices. The link e can also be regarded as a set of two different nodes.

It is assumed that each link e∈E has a state (binary value) of either “normal” or “faulty”. A link that has a value representing “normal” is also referred to as a “normal link” and a link that has a value representing “fault” is also referred to as a “fault link”. It is assumed that N=|N| (total number of nodes) and M=|E| (total number of links).

### Monitoring Path Set P

A set of monitoring paths p is defined as a monitoring path set P. The monitoring path p∈P is a path on G (that is, a column of links connecting different nodes: here, it is assumed that the same node is not routed on the way. However, it is assumed that the same node is not routed on the way). It is assumed that the monitoring path p is expressed as a set of links, for example, p={e₁, e₂, . . . , eₘ}⊂P.

When the monitoring path p includes a faulty link, p is referred to as being “abnormal”. Conversely, when the monitoring path p includes only a normal link, p is referred to as being “normal”.

When the link e is faulty and the other links are normal, a set of monitoring paths Pₑ⊂P that becomes abnormal is written. Hereinafter, in description, it is assumed that two links are not faulty at the same time. Even when there is a simultaneous fault, the formulation can be extended and the embodiment can be similarly applied. Hereinafter, in description, it is assumed that a node fault is not considered and only a link fault can occur. However, even when there is a node fault, the embodiment can be similarly applied by extending the formulation.

As an expression method of the monitoring path set P, a monitoring path matrix B which is a binary matrix of |P| rows and M columns is defined. p₁, p₂, . . . , p_{|P|} are assigned to the monitoring paths in this order, and e₁, e₂, . . . , e_{M} are assigned to all links in this order. At this time, an (i, j) component of the monitoring path matrix B is Bᵢⱼ. Bᵢⱼ=1 is set when pᵢ includes eⱼ, and Bᵢⱼ=0 is set when pᵢ does not include eⱼ.

### Distinguishability and Identifiability

Distinguishability is defined according to Non Patent Literature 2.

It is assumed that the monitoring path set P is given. When the links e₁ and e₂∈E satisfy P_{e_1}≠P_{e_2} (Here, e_1 and e_2 represent e₁ and e₂, respectively), it is said that e₁ and e₂ are distinguishable with respect to P.

It is assumed that the monitoring path set P is given. When a link e∈E is distinguishable with respect to P for any other link e′∈E−[e], it is said that e is identifiable with respect to P.

A link set which is identifiable with respect to P is written as S(P).

On the assumption that the monitoring path matrix B is an arrangement of the vertical vectors b₁, b₂, . . . , b_{M}, a link eᵢ that is identifiable and the link bᵢ that not match any other vertical vector have the same value. The number of identifiable links |S(P)| is none more than the number of vertical vectors that do not match any other vertical vectors among the vertical vectors that configure the monitoring path matrix B.

When the monitoring path pᵢ includes only one of eⱼ and eₖ, in other words, when Bᵢⱼ≠Bᵢₖ (in other words, when only one of pᵢ∈P_{e_j} and pᵢ∈P_{e_k} (where e_j and e_k represent eⱼ and eₖ, respectively) holds), it is said that the monitoring path pᵢ separates eⱼ and eₖ.

In the embodiment, a scheme for two problems the following (i) and (ii) is provided. However, even when the problems do not strictly comply with this, similar problems can be similarly formulated and solved.

### (i) Monitoring Path Selection Problem

Problem: it is assumed that the monitoring path set P and a natural number K (where K≤|P|) are given. At this time, what is a subset of P in which the number of elements is K and the number of identifiable links is maximized? That is, the following formula is obtained.

$$\begin{matrix}[ Math . 3 ] & \\ arg {max}_{\tilde{P} ⊂ P ( \vert \tilde{P} \vert = K )} \vert S ( \tilde{P} ) \vert & \end{matrix}$$

Hereinafter, in the text of the specification, “~” given immediately above a symbol is written as a superscript immediately before the symbol. For example, the subset of P is denoted as ~P.

This problem can be considered as a problem of selecting enumeration of a most effective monitoring path in the sense of being identifiable within a budget (that is, |~P|=K) when any routing rule is predetermined and the implementable monitoring paths are enumerated.

### (ii) Monitoring Path Design Problem

Problem: it is assumed that the natural number K is given. At this time, what is the monitoring path set P in which the number of elements is K and the number of identifiable links is maximized? That is, the following formula is obtained.

$$\begin{matrix}[ Math . 4 ] & \\ arg {max}_{P ( \vert P \vert = K )} \vert S ( P ) \vert & \end{matrix}$$

In this problem, there is no other constraint as long as the monitoring path p∈P is only a route on G. That is, it can be considered as a problem of designing arrangement of a most effective monitoring path in the sense of being identifiable within the budget (that is, |P|=K) under the condition that the routing rule can be freely set for each path.

### <<Details of Proposed Scheme>>

For the foregoing problems (i) and (ii), a method of representing the objective function in the form of HOBO or QUBO will be described. Hereinafter, it is assumed that a simple connected undirected graph G=(V, E) representing a target network is given.

### (i) Solution to Monitoring Path Selection Problem

This problem can be expressed as a minimization problem of an objective function E_{HOBO} in the form of HOBO as expressed in the following Formula (3).

$$\begin{matrix}[ Math . 5 ] & \\ {E}_{HOBO} ( {\{ {z}_{i} \}}_{t} ; λ ) = - {\sum }_{j = 1}^{M} {\prod }_{k ( \neq j )}^{M} [ 1 - {\prod }_{i = 1}^{\vert P \vert} ( 1 - {C}_{i : j , k} {z}_{i} ) ] + {λ ( {\sum }_{i = 1}^{\vert P \vert} {z}_{i} - K )}^{2} & ( 3 )\end{matrix}$$

Here, C_{i;j,k}=C_{i;k,j}=(Bᵢⱼ−Bᵢₖ)² is set.

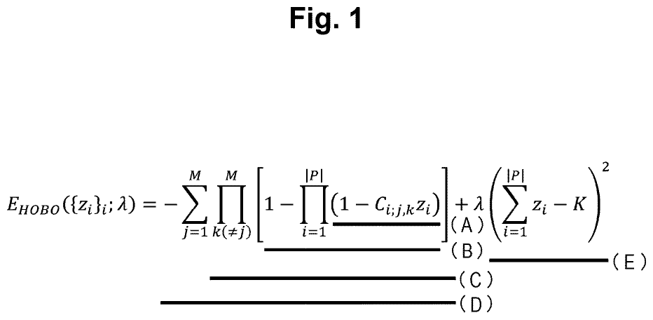

At this time, a variable to be searched for is {zᵢ}ᵢ, and zᵢ takes 1 when the monitoring path pᵢ is adopted as an element of ~P, and takes 0 when the monitoring path pᵢ is not adopted (where i∈{1, 2, . . . , |P|}). In the foregoing Formula (3), when the monitoring path pᵢ is adopted as an element of ~P, a portion of (A) in FIG. 1 is 0 when eⱼ and eₖ can be separated by pᵢ, and is 1 otherwise. A portion (B) is 1 when eⱼ and eₖ are separated by the monitoring path in ~P, and is 0 otherwise. A portion (C) is 1 when eⱼ is identifiable by the monitoring path in ~P, and is 0 otherwise. A portion of (D) represents the number of links that are identifiable by ~P×(−1), and is a minimization target (that is, the number of identifiable links is maximized). A portion (E) is a constraint condition that the number of monitoring paths included in ~P is K.

In the Ising machine, in general, the Constraint condition cannot be clearly specified. Therefore, as in the foregoing Formula (3), a relaxation term is introduced using a penalty λ>0 to take countermeasure so that the value of the objective function increases when the constraint condition is violated. When the value of λ is sufficiently large, it is easy to obtain a solution satisfying the constraint condition. However, the value of λ depends on performance of the Ising machine and has an influence on a result of the optimality of the obtained solution. Therefore, it is necessary to appropriately set the value of λ.

The objective function E_{HOBO} in the form of HOBO expressed in the foregoing Formula (3) can be converted into the form of QUBO by a general methodology. However, in the embodiment, an objective function E_{QUBO} in the form of QUBO is also explicitly given as expressed in the following Formula (4).

$$\begin{matrix}[ Math . 6 ] & \\ {E}_{QUBO} ( {\{ {z}_{i} \}}_{i} , {\{ {x}_{j , α} \}}_{j , α} , {\{ {y}_{j , k : m} \}}_{y , j , m} ; λ ) = - {\sum }_{j = 1}^{M} {x}_{j , 0} + λ {\sum }_{j = 1}^{λ} [ {( 1 - {\sum }_{α = 0}^{M - 1} {x}_{j , α} )}^{2} + {( {\sum }_{k ( \neq j )}^{M} {y}_{j , k ; 0} - {\sum }_{α = 0}^{M - 1} α {x}_{j , α} )}^{2} ] + λ {\sum }_{j , k ( j < k )}^{M} [ {( 1 - {\sum }_{m = 0}^{\vert P \vert} {y}_{j , k ; m} )}^{2} + {( {\sum }_{i = 1}^{\vert P \vert} {C}_{i : j , k} {z}_{i} - {\sum }_{m = 0}^{\vert P \vert} {my}_{j , k : m} )}^{2} ] + {λ ( {\sum }_{i = 1}^{\vert P \vert} {z}_{i} - K )}^{2} & ( 4 )\end{matrix}$$

Here, C_{i;j,k}=C_{i;k,j}=(Bᵢⱼ−Bᵢₖ)² is set. At this time, variables to be searched are as follows.

zᵢ: a variable that takes 1 when the monitoring path pᵢ is adopted as an element of ~P and takes 0 when the monitoring path pᵢ is not adopted (where i∈{1, 2, . . . , |P|}).

With respect to ~P determined by x_{j,α}:zᵢ, a variable that takes 1 when the number of links eⱼ and links that are not distinguishable from the link eⱼ is α, and takes 0 otherwise (where j∈{1, 2, . . . , M} and α∈{0, 1, . . . , M−1}).

A variable (where j and k∈{1, 2, . . . , M} and m∈{0, 1, . . . , |P|})) that takes 1 when the number of monitoring paths that separate the links eⱼ and eₖ among the monitoring paths p∈~P included in ~P determined by y_{j,k,m}: zᵢ is m, and takes 0 otherwise.

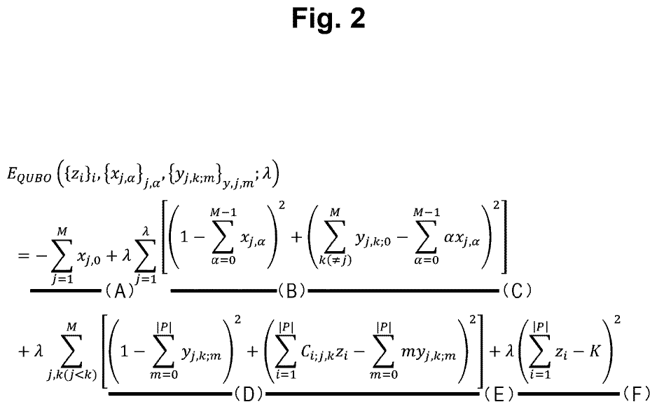

In the foregoing Formula (4), a portion (A) in FIG. 2 represents the number of identifiable links×(−1) and is a minimization target. A portion (B) represents a constraint condition caused by the definition of x_{j,α}. A portion (C) is a constraint condition (an equation related to the number of links that are not distinguishable from the link eⱼ) representing a relation established between x_{j,α} and y_{j,k,0}. A portion (D) is a constraint condition caused by the definition of y_{j,w,m}. A portion (E) is a constraint condition (an equation related to the number of monitoring paths that separate the links eⱼ and eₖ) representing a relation established between y_{j,w,m} and zᵢ. A portion (F) is a constraint condition that the number of monitoring paths included in ~P is K.

In the foregoing Formula (4), the common weight λ is used for the relaxation term of the constraint condition, but different values may be adopted.

### (ii) Solution to Monitoring Path Design Problem

The objective function for this problem must reflect the constraint condition that the monitoring path p∈P is a path on G. Therefore, several preparations are made.

Definition (link guidance part graph): a part graph G′=(V′, E′) of an undirected graph G=(V, E), where V′={v∈V′|∃e∈E′, v∈e} is referred to as a link guidance part graph of G.

Lemma 1: necessary and sufficient conditions for the link guidance part graph G′=(V′, E′) of the undirected graph G=(V, E) to be a route on G (to be exact, the route on G is obtained when an appropriate column is formed with links in E′) satisfies the following two conditions.
Condition 1-1: in G′, exactly two vertices are degree of 1, and the other vertices are degree of 2.
Condition 1-2: G′ has no closed route.

Since Lemma 1 is obvious, its proof will be omitted.

Lemma 2: necessary and sufficient conditions that the undirected graph G=(V, E) has no closed route is that there are a node height function h: V→{0, 1, . . . , N−1} and a link height function h′: E→{1, 2, . . . , N−1} satisfying the following three conditions.
Condition 2-1: for all nodes u, v∈V, |h(v)−h(u)|=1 when u and v are adjacent.
Condition 2-2: for all links e={vₑ⁰, vₑ¹}∈E, h′(e)=max {h(vₑ⁰), h(vₑ¹)} holds.
Condition 2-3: for all nodes v∈V, at most one of links {eᵥⁱ}ᵢ connected to v satisfies h′(eᵥⁱ)=h(v).

(Proof) necessity: when the undirected graph G is a tree, it is sufficient to indicate ∃ of functions h and h′. Let any v₀∈V be the root h(v₀)=0. For other nodes v∈V−{v₀}, when the height of each node (a length of the path to the root) is set to h(v) and h′ is defined such that Condition 2-2 is satisfied, Conditions 2-1 and 2-3 are satisfied. Sufficiency: it is assumed that there are functions h and h′ satisfying Conditions 2-1, 2-2, and 2-3. G has a closed route (v₀, v₁, . . . , vₙ, v₀), the following formula is defined.

$$\begin{matrix}[ Math . 7 ] & \\ {v}_{0} = arg {max}_{i ∈ \{ 0 , 1 , … , n \}} h ( {v}_{i} ) & \end{matrix}$$

At this time, h(v₁)=h(vₙ)−1, h′({v₀, v₁})=h′({v₀, vₙ})=h(v₀) are obtained from Conditions 2-1 and 2-2. However, since this is contrary to Condition 2-3, the undirected graph G has no closed route.

Lemma 3: necessary and sufficient conditions that the undirected graph G=(V, E) has no closed route is that there are a node height function h: V→{0, 1, . . . , N−1} and a directed link height function ~h: ~E→{0, 1, 2, . . . , N 1} satisfying the following three conditions. Here, ~E is a set of directed links. That is, ~E={(u, v)|∃e∈E, u∈e, v∈e, u≠v}.

Condition 3-1: for all nodes u, v∈V, |h(v)−h(u)|=1 when u and v are adjacent.

Condition 3-2: for all links e={vₑ⁰, vₑ¹}∈E, when h(vₑ⁰)≥h(vₑ¹), ~h((vₑ⁰, vₑ¹))=0 and ~h ((vₑ¹, vₑ⁰))=h(vₑ⁰) hold, and when h(vₑ⁰)<h(vₑ¹), ~h((vₑ⁰, vₑ¹))=h(vₑ¹) and ~h((vₑ¹, vₑ⁰))=0 hold.

Condition 3-3: for all nodes v∈V, at most one of the directed links {~eᵥⁱ} i having v as an end point is ~h(eᵥⁱ)=h(v) when h(v)≠0.

(Proof) necessity: from Lemma 2, there are h and h′ that satisfy Conditions 2-1, 2-2, and 2-3. At this time, for the link e=(u, v), when h(u)≥h(v), ~h ((u, v))=0, ~h((v, u))=h′({u, v}), when h(u)≥h(v), ~h((u, v))=h′({u, v}), ~h((v, u))=0, and when the directed link height function ~h is determined, h and ~h satisfy Conditions 3-1, 3-2, and 3-3. Sufficiency: it is assumed that there are the functions h and ~h satisfying Conditions 3-1, 3-2, and 3-3. At this time, for the link e={u, v}, when the link height function h′ is determined by h′(e)=max{~h(u, v), ~h(v, u)}, h and h′ satisfy Conditions 2-1, 2-2, and 2-3. Accordingly, from Lemma 2, G=(V, E) has no closed route,

From the above, it can be understood that in order to ensure that the monitoring path p∈P is a route on G, it is only required that Condition 1-1 of Lemma 1 hold and there are the functions h and h satisfying Conditions 3-1 to 3-3 of Lemma 3. Based on these, this problem can be expressed as a minimization problem of the objective function E_{QUBO} in the form of QUBO as expressed in the following Formula (5).

$$\begin{matrix}[ Math . 8 ] & \\ {E}_{QUBO} ( {\{ {x}_{\text{?}} \}}_{\text{?}} {\{ {y}_{\text{?}} \}}_{\text{?}} {\{ {q}_{\text{?}} \}}_{\text{?}} {\{ {r}_{\text{?}} \}}_{\text{?}} {\{ {s}_{\text{?}} \}}_{\text{?}} , {\{ {h}_{\text{?}} \}}_{\text{?}} {\{ {h}_{\text{?}} \}}_{\text{?}} ; λ ) = - {\sum }_{j = 1}^{M} {x}_{j , 0} + λ {\sum }_{j = 1}^{M} [ {( 1 - {\sum }_{α = 0}^{M - 1} {x}_{j , α} )}^{2} + {( {\sum }_{k ( \neq j )}^{M} {y}_{\text{?}} - {\sum }_{α = 0}^{M - 1} α {x}_{\text{?}} )}^{2} ] + λ {\sum }_{j , k ( j < k )}^{M} \{ {( 1 - {\sum }_{m = 0}^{K} {y}_{\text{?}} )}^{2} + {( {\sum }_{i = 1}^{K} {\sum }_{m ∈ \{ \pm 1 \}} {s}_{\text{?}} - {\sum }_{m = 0}^{K} {my}_{\text{?}} )}^{2} + {\sum }_{i = 1}^{K} [ {( 1 - {\sum }_{m ∈ \{ \}} {s}_{\text{?}} )}^{2} + {( {q}_{ij} - {q}_{ik} - {\sum }_{m ∈ \{ \text{?} \}} )}^{2} ] \} + λ {\sum }_{i = 1}^{K} [ {\sum }_{l = 1}^{N} {( 1 - {\sum }_{m = 0}^{2} {r}_{\text{?}} )}^{2} + {\sum }_{l = 1}^{N} {( {\sum }_{\text{?}} {q}_{ik} - {\sum }_{m = 0}^{2} {mr}_{\text{?}} )}^{2} + {( {\sum }_{l = 1}^{N} {r}_{\text{?}} - 2 )}^{2} ] + λ {\sum }_{i = 1}^{K} [ {\sum }_{l = 1}^{N} {( 1 - {r}_{\text{?}} - {\sum }_{\text{?}}^{\text{?}} {h}_{\text{?}} )}^{2} + {\sum }_{k = 1}^{M} {( {q}_{\text{?}} - {\sum }_{\text{?}}^{N - 1} ( {h}_{\text{?}} + {h}_{\text{?}} ) )}^{2} + {\sum }_{l = 1}^{N} {\sum }_{\text{?}}^{N - 1} {( {h}_{\text{?}} {\sum }_{\text{?}} {h}_{\text{?}} )}^{2} + {\sum }_{l = 1}^{N} {\sum }_{\text{?}} {\sum }_{β \text{?}}^{N - 1} {h}_{\text{?}} ( 2 - {h}_{\text{?}} - {h}_{\text{?}} ) ] & ( 5 )\end{matrix}$$

$$\text{?} \text{indicates text missing or illegible when filed}$$

Here, V₁ is a set of subscripts of nodes adjacent to a node v₁ in G. Eᵢ is a set of subscripts of links connected to the node v₁ in G.

At this time, variables to be searched are as follows. Here, P is a provisional solution of the monitoring path set.

For x_{j,α}: P, a variable that takes 1 when the number of links eⱼ and links that are not distinguishable from the link eⱼ is, and takes 0 otherwise (where j∈{1, 2, . . . , M}, α∈{0, 1, . . . , M−1}).

In y_{j,k;m}: a variable that takes 1 when the number of monitoring paths p∈P that separate the links eⱼ and eₖ is m, and takes 0 otherwise (where j and k∈{1, 2, . . . , M} and m∈{0, 1, . . . , K}).

s_{i;j,k;m}: a variable that takes s_{i;j,k;0}=1 when both the links eⱼ and eₖ are included in the monitoring path pᵢ∈P, or both the links eⱼ and eₖ are not included, takes s_{i;j,k;1}=1 when only the link eⱼ is included, and takes s_{i;j,k;-1}=1 when only the link eₖ is included (where i∈{1, 2, . . . , K}, j, k∈{1, 2, . . . , M}, and m∈{0, 1,−1}).

qᵢⱼ: a variable that takes 1 when the link eⱼ is included in the monitoring path pᵢ∈P and takes 0 otherwise (where i∈{1, 2, . . . , K} and j∈{1, 2, . . . , M}).

r_{i;l,m}: a variable that takes 1 when the degree of the node vₗ is m and takes 0 otherwise, for the part graph pᵢ that is a monitoring path candidate but is not necessarily a route, (where i∈{1, 2, . . . . K}, l∈{1, 2, . . . , N}, and m∈{0, 1, 2}).

h_{i;l,β}: a variable that, for the part graph pᵢ, takes 1 when the value of the height function h(vₗ) for the node vₗ is β, and takes 0 otherwise (where i∈{1, 2, . . . . K}, l∈{1, 2, . . . , N}, and β∈{0, 1, . . . , N−1}).

~h_{i;l,l′;β}: a variable that, for the part graph pᵢ, takes 1 when the value of the height function ~h((vₗ, vₗ′)) of the directed link with respect to the directed link (vₗ, vₗ′) is β, and takes 0 otherwise (where i∈{1, 2, . . . . K}, l and l′∈{1, 2, . . . , N}, and β∈{1, . . . , N−1}),

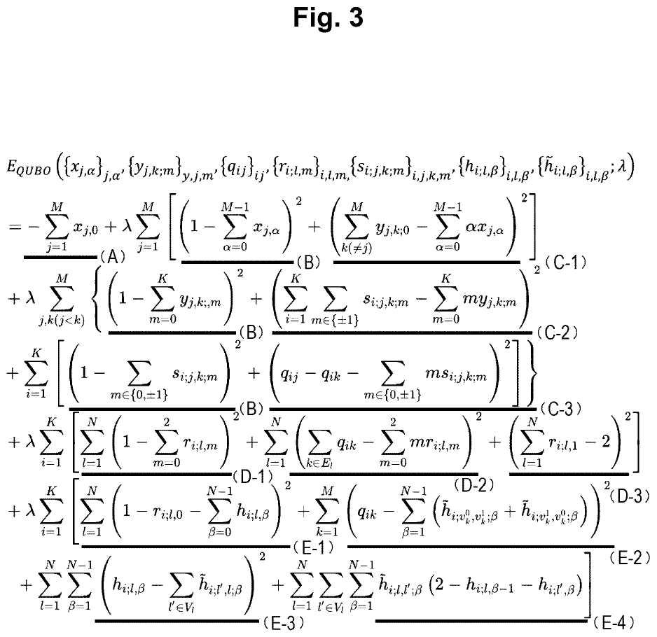

In the foregoing Formula (5), a portion (A) in FIG. 3 represents the number of identifiable links×(−1), and is a minimization target. A portion (B) represents a constraint condition resulting from definitions of x_{j,α}, y_{j,k,m}. s_{i;j,k;m} respectively. (C-1) to (C-3) indicate constraint conditions representing a relation established between variables, and (C-1) is an equation for the number of links that are not distinguishable from the links eⱼ. A portion (C-2) is an equation related to the number of monitoring paths that separate the links eⱼ and eₖ. A portion of (C-3) is an equation indicating whether the monitoring path pᵢ includes the links eⱼ and eₖ. (D-1) to (D-3) are constraint conditions related to the degree of vertexes, and correspond to Condition 1-1 of Lemma 1. The portion of (D-1) indicates that all the vertices have the degree of 0, 1, or 2. The portion (D-2) indicates that the degree of 0 is a node outside of the monitoring path, the degree of 1 is nodes at both ends of the monitoring path, and the degree of 2 is a node inside the monitoring path and other than both ends. The portion of (D-3) indicates that exactly 2 nodes have the degree of 1. (E-1) to (E-3) are constraint conditions that the monitoring path has no closed route, and correspond to Condition 1-2 of Lemma 1. The portion (E-1) is a constraint condition resulting from the definition of the node height function and indicates that the node height function gives an integer value in [0, β−1] in the case of a node in the monitoring path, and the node height function is not defined in the case of a node outside of the monitoring path. The portion (E-2) is a constraint condition resulting from the definition of the directed link height function and indicates that one of the two directed link height functions gives an integer value within [1, N−1] and the other gives 0 in the case of a link within the monitoring path, and the directed link height function is not defined in the case of a link outside of the monitoring path. The portion (E-3) corresponds to Condition 3-3 in Lemma 3. The portion (E-4) corresponds to Conditions 3-1 and 3-2 of Lemma 3.

In the foregoing Formula (5), the common weight λ is used for the relaxation term of the constraint condition, but different values may be adopted.

### <Hardware Configuration Example of Monitoring Path Design Device 10>

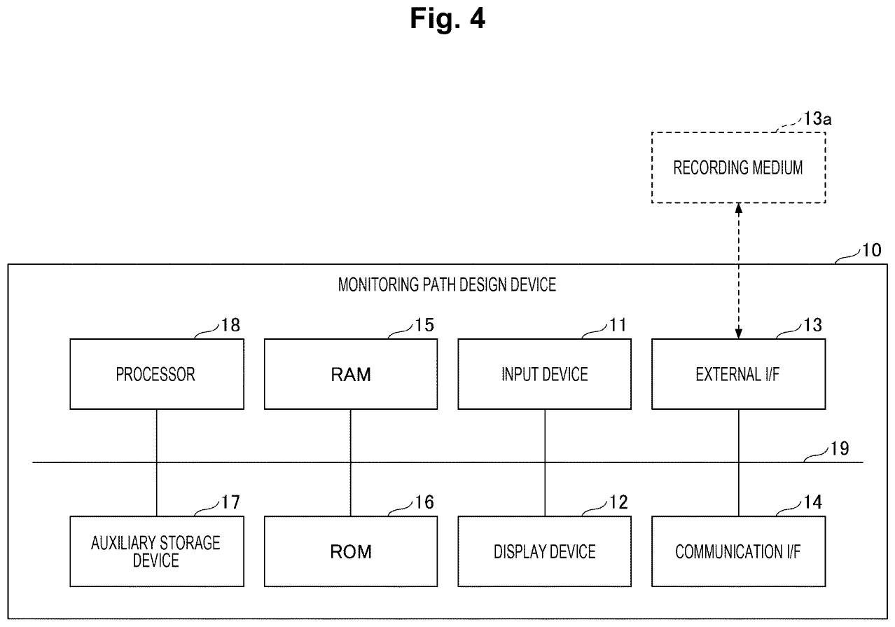

FIG. 4 illustrates a hardware configuration example of the monitoring path design device 10 according to the embodiment. As illustrated in FIG. 4, the monitoring path design device 10 according to the embodiment includes an input device 11, a display device 12, an external I/F 13, a communication I/F 14, a random access memory (RAM) 15, a read only memory (ROM) 16, an auxiliary storage device 17, and a processor 18. Each hardware is communicably connected via a bus 19.

The input device 11 is, for example, a keyboard, a mouse, a touch panel, a physical button, or the like. The display device 12 is, for example, a display, a display panel, or the like. The monitoring path design device 10 may not include, for example, at least one of the input device 11 and the display device 12.

The external I/F 13 is an interface with an external device such as a recording medium 13a. The monitoring path design device 10 can read and write the recording medium 13a via the external I/F 13. Examples of the recording medium 13a include a flexible disk, a compact disc (CD), a digital versatile disk (DVD), a secure digital memory card (SD memory card), and a Universal Serial Bus (USB) memory card.

The communication I/F 14 is an interface for connecting the monitoring path design device 10 to a Communication network. The RAM 15 is a volatile semiconductor memory (storage device) that temporarily retains programs and data. The ROM 16 is a nonvolatile semiconductor memory (storage device) capable of retaining a program and data even when power is turned off. The auxiliary storage device 17 is, for example, a storage device (storage device) such as a hard disk drive (HDD), a solid state drive (SSD), or a flash memory. The processor 18 is, for example, an arithmetic device such as a central processing unit (CPU).

The monitoring path design device 10 according to the embodiment has the hardware configuration illustrated in FIG. 4, and thus it is possible to implement a monitoring path design process to be described below. The hardware configuration illustrated in FIG. 4 is exemplary, and the hardware configuration of the monitoring path design device 10 is not limited thereto. For example, the monitoring path design device 10 may include a plurality of auxiliary storage devices 17 and a plurality of processors 18, may not include a part of the illustrated hardware, or may include various types of hardware other than the illustrated hardware.

<Functional Configuration Example of Monitoring Path Design Device 10>

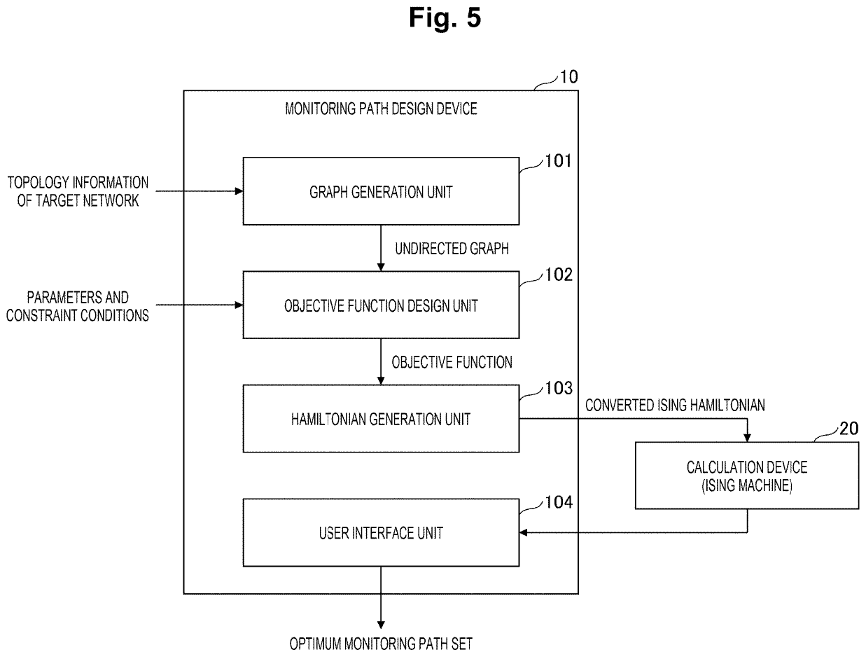

A functional configuration example of the monitoring path design device 10 according to the embodiment is illustrated in FIG. 5. As illustrated in FIG. 5, the monitoring path design device 10 according to the embodiment includes a graph generation unit 101, an objective function design unit 102, a Hamiltonian generation unit 103, and a user interface unit 104. It is assumed that topology information of the target network, and parameters (λ, K, and the like) and constraint conditions of the monitoring path selection problem described in the foregoing (i) or the monitoring path design problem described in the foregoing (ii) are given to the monitoring path design device 10. The topology information is information indicating a network device included in the target network and a connection relation.

The graph generation unit 101 generates the undirected graph G (more precisely, the simple connected undirected graph G) from the given topology information.

The objective function design unit 102 generates an objective function in the form of HOBO or the form of QUBO using the undirected graph G generated by the graph generation unit 101 and the given parameters and constraint conditions. That is, the objective function design unit 102 generates the objective function E_{HOBO} expressed in the foregoing Formula (3) or the objective function E_{QUBO} expressed in the foregoing Formula (4) when the monitoring path selection problem described in the foregoing (i) is solved, and generates the objective function E_{QUBO} expressed in the foregoing Formula (5) when the monitoring path design problem described in the foregoing (ii) is solved.

The Hamiltonian generation unit 103 converts the objective function generated by the objective function design unit 102 into the Ising Hamiltonian, and then converts the Ising Hamiltonian into a form that can be solved by the calculation device 20 that is an Ising machine. That is, the Hamiltonian generation unit 103 performs processes related to the foregoing steps 2 and 3. Hereinafter, the Ising Hamiltonian converted into the form that can be solved by the calculation device 20 is referred to as a converted Ising Hamiltonian. The Hamiltonian generation unit 103 may lower the degree of the objective function in the form of HOBO to the form of QUBO as necessary, and then convert the objective function in the form of QUBO into the Ising Hamiltonian.

The Hamiltonian generation unit 103 transmits the converted Ising Hamiltonian to the calculation device 20. Accordingly, the calculation device 20 that is an Ising machine obtains an optimum monitoring path set as an optimum solution (more correctly, a quasi-optimum solution).

The user interface unit 104 displays the optimum monitoring path set calculated by the calculation device 20 on a user interface such as the display device 12. The present invention is not limited thereto and the user interface unit 104 may store, for example, the optimum monitoring path set in the auxiliary storage device 17 or the like.

In the example illustrated in FIG. 5, the calculation device 20 that is an Ising machine is located outside of the monitoring path design device 10. The present invention is not limited thereto and the monitoring path design device 10 may include a calculation unit that functions as an Ising machine.

### <Monitoring Path Design Process>

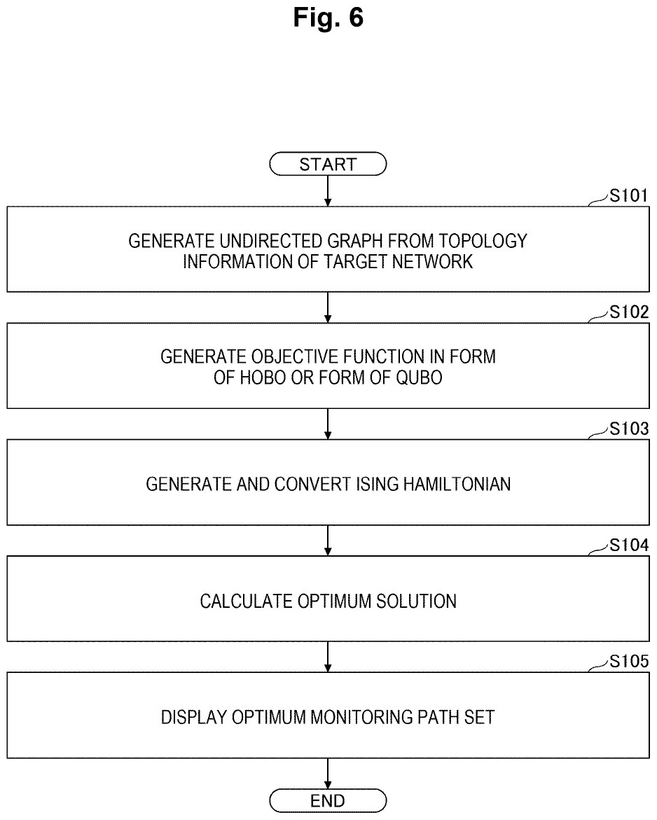

A flow of the monitoring path design process according to the embodiment will be described with reference to FIG. 6.

The graph generation unit 101 generates the undirected graph G from the given topology information (step S101).

Subsequently, the objective function design unit 102 generates an objective function (the objective function expressed in Formula (3) or Formula (4) or the objective function expressed in Formula (5)) in the form of HOBO or the form of QUBO using the undirected graph G generated in the foregoing step S101 and the given parameters and constraint conditions (step S102).

Subsequently, the Hamiltonian generation unit 103 converts the objective function in the form of HOBO or the form of QUBO generated in step S102 described above into the Ising Hamiltonian, and then converts the objective function into a form that can be solved by the calculation device 20 that is an Ising machine (step S103). As a result, the converted Ising Hamiltonian is generated.

Subsequently, the Hamiltonian generation unit 103 transmits the converted Ising Hamiltonian generated in the foregoing step S103 to the calculation device 20 (step S104). Accordingly, the optimum monitoring path set is calculated as an optimum solution by the calculation device 20 using the converted Ising Hamiltonian.

Then, the user interface unit 104 displays the optimum monitoring path set calculated by the calculation device 20 on a user interface such as the display device 12 (step S105).

### CONCLUSION

As described above, the monitoring path design device 10 according to the embodiment formulates a problem that maximizes an objective function indicating effectiveness of the monitoring path into a form that can be solved by the Ising machine called HOBO or QUBO. Accordingly, it is possible to obtain a quasi-optimum solution that is considered to have higher network state segmentation performance by any Ising machine. In the Ising machine, since an optimum solution is widely searched from the entire search space, it is considered that a solution superior to a technique of the related art can be found. Many calculation examples in which the Ising machine shows higher performance than a classical computer have been reported. It is expected that more large-scale calculation is possible when the number of quantum bits available in the future increases. Therefore, even when a large-scale network system that cannot be treated in the technique of the related art is set as a target, it is possible to design a monitoring path with higher performance, and implementation of a high-quality network operation can be expected.

The present invention is not limited to the foregoing specifically disclosed embodiment, and various modifications and changes, combinations with known technique, and the like can be made without departing from the scope of the claims.

### REFERENCE SIGNS LIST

10 Monitoring path design device
11 Input device
12 Display device
13 External I/F
13a Recording medium
14 Communication I/F
15 RAM
16 ROM
17 Auxiliary storage device
18 Processor
19 Bus
20 Calculation device
101 Graph generation unit
102 Objective function design unit
103 Hamiltonian generation unit
104 User interface unit

1. A monitoring path design device that designs a monitoring path for estimating a state of a target network, the monitoring path design device comprising:
a processor; and
a memory storing program instructions that cause the processor to
generate an objective function representing effectiveness of the monitoring path in a form that is calculable by an Ising machine using an undirected graph representing a topology of the target network.

2. The monitoring path design device according to claim 1,
wherein the effectiveness of the monitoring path is segmentation performance of the state of the target network, and
wherein the program instructions cause the processor to set, as a target, a problem for selecting a set of monitoring paths having high segmentation performance of the state of the target network from a plurality of candidates for the monitoring path under a given constraint condition and generates a form of HOBO or a form of QUBO of a function which is an optimization target for the problem as the objective function.

3. The monitoring path design device according to claim 1,
wherein the effectiveness of the monitoring path is segmentation performance of the state of the target network, and
wherein the program instructions cause the processor to set, as a target, a problem of designing a set of monitoring paths having high segmentation performance of the state of the target network under a given constraint condition and generates a form of QUBO of a function which is an optimization target for the problem as the objective function.

4. The monitoring path design device according to claim 1, further comprising a display device configured to output a set of monitoring paths calculated by the Ising machine from the objective function to a user interface.

5. A monitoring path design method comprising generating, by a monitoring path design device that designs a monitoring path for estimating a state of a target network,
an objective function representing the effectiveness of the monitoring path in a form that is calculable by an Ising machine using an undirected graph representing a topology of the target network.

6. A non-transitory computer-readable recording medium having stored therein a program causing a monitoring path design device that designs a monitoring path for estimating a state of a target network to perform:
generating an objective function representing the effectiveness of the monitoring path in a form that is calculable by an Ising machine using an undirected graph representing a topology of the target network.
